(19) United States
(12) Patent Application Publication
(10) Pub. No.: US 2024/0431072 A1
(43) Pub. Date: Dec. 26, 2024

(54) METHOD FOR REPLACING THE LIQUID IN A COOLING CIRCUIT OF A SUPERCOMPUTER RACK

(71) Applicant: BULL SAS, Les Clayes-sous-Bois (FR)

(72) Inventors: Arnaud HILT, AUFFARGIS (FR); Eimed NADIFI, AVRILLE (FR)

(73) Assignee: BULL SAS, Les Clayes-sous-Bois (FR)

(21) Appl. No.: 18/745,927

(22) Filed: Jun. 17, 2024

(30) Foreign Application Priority Data
Jun. 20, 2023 (EP) 23305974.0

(51) Int. Cl. H05K 7/20

(52) U.S. Cl. CPC H05K 7/20272; H05K 7/20627

(57) ABSTRACT

The invention relates to a method for replacing liquid in a liquid cooling circuit in a supercomputer rack, including a main pump and a reserve pump, using a maintenance unit. The method includes disconnecting the reserve pump, connecting the upstream reservoir to the reserve pump, connecting the downstream reservoir, stopping the main pump, activating the reserve pump, stopping the reserve pump once the upstream reservoir is below a predetermined low threshold, disconnecting the upstream reservoir from the reserve pump, disconnecting the reserve pump from the downstream reservoir, connecting the inlet supply pipe to the reserve pump in order to return said reserve pump to its initial configuration and reactivating the main pump.

This application claims priority to European Patent Application Number 23305974.0, filed 20 Jun. 2023, the specification of which is hereby incorporated herein by reference.

### BACKGROUND OF THE INVENTION

### Technical Field of the Invention

At least one embodiment of the invention relates to the field of the liquid cooling of the supercomputers and more particularly concerns a method for replacing the liquid in a cooling circuit of a supercomputer rack.

### Description of the Related Art

Today, more and more fields are using High Performance Computing (HPC) to process computer operations.

The processors that carry out these high-performance computing are usually installed in racks, which may themselves be located in computing centers.

These processors may get very hot, so they need to be cooled to ensure optimum performance and to prevent damage to their components. For example, the supercomputer racks, which contain several computing blades to which several processors are connected, require a cooling system.

This cooling system is usually mounted in the rack and comprises a closed hydraulic circuit in which a cooling liquid is circulated by a pump referred to as “main” pump. To prevent the supercomputer rack from shutting down if the main pump fails, a pump referred to as “reserve” pump is usually installed in the circuit in parallel with the main pump so as to take over if the main pump fails.

To maintain the cooling efficiency, the liquid circulating in the hydraulic cooling circuit must be changed regularly. The most common solution is to manually drain the circuit of used cooling liquid by opening the circuit at a low point via a system of valves and allowing the liquid to drain by gravity into a recovery reservoir. Once the circuit has been emptied, a drying period is observed, then the circuit is closed again via the valve system.

The circuit is then connected to a maintenance unit comprising a reservoir containing the new cooling liquid and a maintenance pump. Once the maintenance unit connected to the cooling circuit of the rack, with the main pump always off, the maintenance pump is activated manually to circulate the new cooling liquid and thus fill the circuit.

However, this solution means that the computing blades have to be stopped while the circuit dries and the circuit is filled with the new liquid. You will also have to wait for the blades to restart completely before you may use them again. The total downtime of the computing blades, which may be significant, reduces their performance and therefore their efficiency, which is a major disadvantage.

In addition, the manual handling of the various valves and pumps in the rack may lead to errors that may damage the components.

So, there is a need for a simple, efficient solution that will allow at least partially to remedy these disadvantages.

### BRIEF SUMMARY OF THE INVENTION

To this end, at last one embodiment of the invention is a method for replacing the liquid in a liquid cooling circuit of a supercomputer rack by means of a maintenance unit, said rack comprising a liquid cooling circuit, a main pump mounted in said liquid cooling circuit and a reserve pump mounted in parallel with said main pump via an inlet supply pipe connected upstream from said main pump and an outlet supply pipe connected downstream from said main pump, said maintenance unit comprising an upstream reservoir for new cooling liquid and a downstream reservoir for recovering the used cooling liquid, said method comprising the steps of:
disconnecting the inlet supply pipe from the reserve pump,
connecting the inlet supply pipe to the downstream reservoir,
connecting the upstream reservoir to the inlet of the reserve pump via a “drain” pipe,
stopping the main pump,
activating the reserve pump so as to circulate the cooling liquid from the upstream reservoir to the downstream reservoir via the reserve pump,
stopping the reserve pump once the new cooling liquid in the upstream reservoir is below a predetermined low threshold,
disconnecting the drain pipe to disconnect the upstream reservoir from the reserve pump,
disconnecting the inlet supply pipe from the downstream reservoir,
connecting the inlet supply pipe to the inlet of the reserve pump in order to return said reserve pump to its initial configuration,
reactivating the main pump.

This method, by way of one or more embodiments, allows to eliminate the need to stop the active components of the computing blades of the supercomputer rack, which may therefore continue to operate while the cooling liquid is being replaced. This method, by way of one or more embodiments, does not require any modification to the supercomputer racks, since the fact that they are equipped with a reserve pump is known to the prior art, and may therefore be adapted to the existing equipment.

Preferably, in at least one embodiment, the steps of stopping the main pump, activating the reserve pump, stopping the reserve pump once the new cooling liquid in the upstream reservoir is below a predetermined low threshold and reactivating the main pump are carried out automatically. As a result, these operations are less arduous to perform for the operator and the method avoids adjustment errors that may damage the liquid cooling circuit.

Alternatively, in at least one embodiment, the steps of the method for stopping the main pump, activating the reserve pump, stopping the reserve pump once the new cooling liquid in the upstream reservoir is below a predetermined low threshold and reactivating the main pump are carried out manually by the operator who adjusts each of the pumps one by one.

Even more preferably, in one or more embodiments, the maintenance unit comprises a maintenance pump at the outlet of the upstream reservoir, said maintenance pump being connected to the reserve pump via the drain pipe, and the method as presented above comprises a step of activating said maintenance pump, preferably simultaneously with the activation of the reserve pump. This step of activating the maintenance pump allow to back up the reserve pump so as to prevent the excessive pressure drops in the liquid cooling circuit, which would prevent the new cooling liquid from being circulated.

At least one embodiment of the invention also relates to a cooling liquid drain system for a supercomputer, said system comprising:
a supercomputer rack configured to receive computing blades and comprising a liquid cooling circuit, a main pump mounted in said liquid cooling circuit and a reserve pump mounted in parallel with said main pump,
a removable maintenance unit comprising an upstream reservoir for new cooling liquid and a downstream reservoir for recovering used cooling liquid, each configured to be connected to the rack,
a control module configured to control the main pump and the reserve pump of the rack.

Preferably, in at least one embodiment, the control module is configured so as, in an automatic maintenance mode, automatically to carry out the following sequence: command the stop of the main pump, then command the activation of the reserve pump, then command the stop of the reserve pump once the liquid in the upstream reservoir is below a predetermined low threshold, then command the reactivation of the main pump.

Alternatively, in at least one embodiment, the automatic maintenance mode may be triggered by an operator, for example by pressing a button on the control module.

Preferably, the control module is configured to detect that the liquid in the upstream reservoir is below a predetermined low threshold.

Even more preferably, in at least one embodiment, the maintenance unit comprises a maintenance pump at the outlet of the upstream reservoir, the outlet of said maintenance pump being configured to be connected to the inlet of the reserve pump of the rack by a drain pipe, the control module being configured to command the activation of said maintenance pump.

Advantageously, in at least one embodiment, the control module is configured to command the activation of the reserve pump and the activation of the maintenance pump simultaneously.

Preferably, in at least one embodiment, the maintenance unit is configured to detect during a drain operation that the liquid in the upstream reservoir is below a predetermined low threshold and to indicate to the control module or to an operator, for example visually, that the liquid in the upstream reservoir is below a predetermined low threshold.

Even more preferably, in at least one embodiment, the maintenance unit comprises at least one filtration module.

Preferably, in at least one embodiment, the filtration module is mounted at the inlet of the downstream reservoir.

In at least one embodiment, the control module is internal to the rack.

In at least one embodiment, the control module is internal to the maintenance unit.

In at least one embodiment, the control module is external to the rack and to the maintenance unit.

### BRIEF DESCRIPTION OF THE DRAWINGS

Other characteristics and advantages of the one or more embodiments of the invention will become apparent from the following description. This is purely illustrative and should be read in conjunction with the attached drawings in which:

FIG. 1 shows an embodiment of the system according to one or more embodiments of the invention before the maintenance unit is connected to the rack.

FIG. 2 schematically illustrates one embodiment of the system according to one or more embodiments of the invention after the maintenance unit has been connected to the rack.

FIG. 3 schematically illustrates the system shown in FIG. 2, which also comprises a command link between the rack and the maintenance unit, according to one or more embodiments of the invention.

FIG. 4 illustrates the steps in the method according to one or more embodiments of the invention.

### DETAILED DESCRIPTION OF THE INVENTION

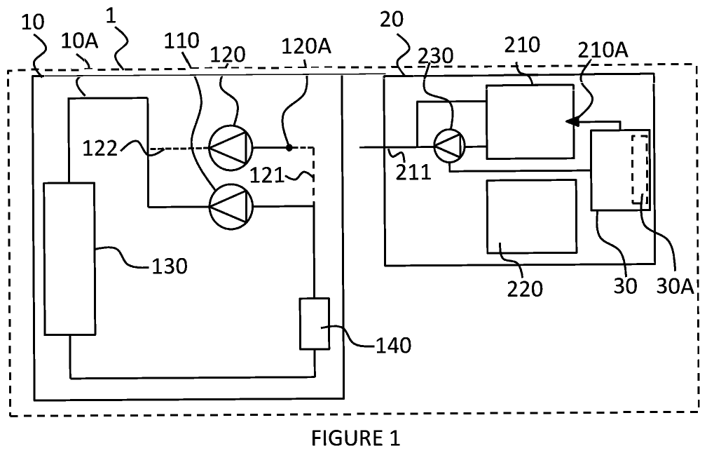

FIG. 1 schematically illustrates an example of a system 1 according to one or more embodiments of the invention.

### System 1

The system 1 comprises a rack 10, a maintenance unit 20 and a control module 30.

### Rack 10

The rack 10 comprises a plurality of computing blades (not shown), a hydraulic liquid cooling circuit 10A for cooling the active elements of said computing blades, a main pump 110, a reserve pump 120, a computing blade heat exchanger 130 and a secondary heat exchanger 140.

The liquid cooling circuit 10A connects the main pump 110, the computing blade heat exchanger 130 and the secondary heat exchanger 140 via fluid connections.

The main pump 110 circulates the cooling liquid in the liquid cooling circuit 10A.

The reserve pump 120 is placed in parallel with the main pump 110 and its function is to replace the main pump 110 in the event of failure of the latter in order to ensure the circulation in the liquid cooling circuit 10A.

The reserve pump 120 has an inlet orifice 120A. An inlet supply pipe 121 is connected to this inlet orifice 120A and is connected to the liquid cooling circuit 10A upstream of the main pump 110.

An outlet supply pipe is connected to the reserve pump 120 and is connected to the liquid cooling circuit 10A downstream of the main pump 110.

The computing blade heat exchanger 130 allows the active elements of the computing blades (not shown in the figures) to be cooled by the cooling liquid circulating in the liquid cooling circuit 10A.

The secondary heat exchanger 140 allows the cooling liquid to be cooled after passing through the computing blade heat exchanger 130 to maintain the cooling function of the liquid cooling circuit 10A.

The rack 10 may be manually adjusted to maintenance mode, in which the main pump 110 is stopped and the reserve pump 120 is started.

### Maintenance Unit 20

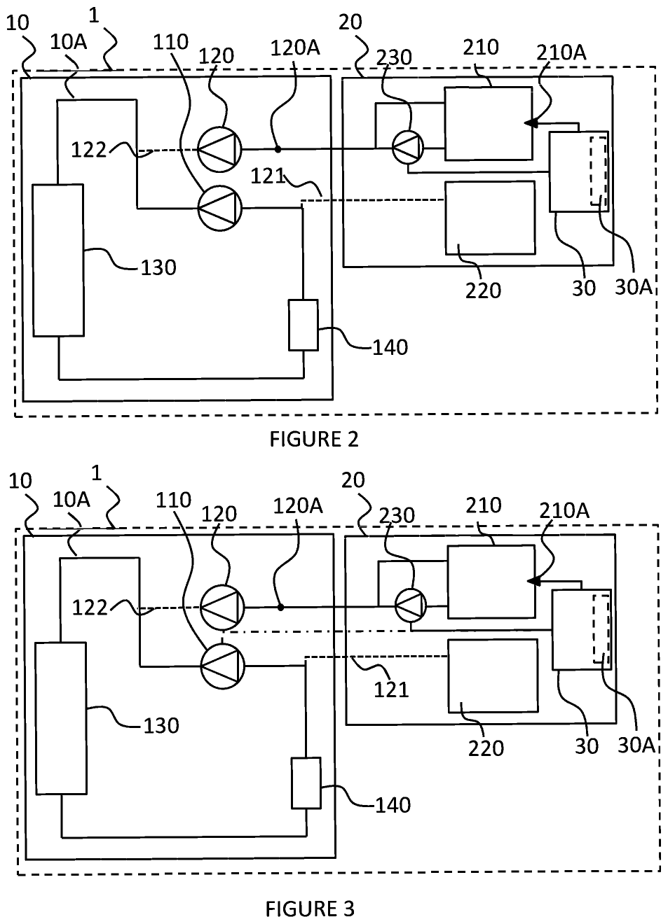

With reference to FIG. 2, the maintenance unit 20 is connected to the rack 10 to perform the steps of the method according to one or more embodiments of the invention.

The maintenance unit 20 comprises an upstream reservoir 210 for new cooling liquid, a downstream reservoir 220 for recovering the used cooling liquid, and a maintenance pump 230.

The upstream reservoir 210 contains the new cooling liquid, which is intended to replace the used liquid in the liquid cooling circuit 10A. The upstream reservoir 210 comprises a liquid level sensor 210A which is electrically connected to the control module 30 or communicates with the control module 30.

A drain pipe 211 is connected to the upstream reservoir 210 and allows the new cooling liquid to circulate towards the liquid cooling circuit 10A during the cooling liquid replacement operation.

When the maintenance unit 20 is connected to the rack 10, the drain pipe 211 is connected to the inlet orifice 120A of the reserve pump 120.

The downstream reservoir 220 is used to recover used cooling liquid from the liquid cooling circuit 10A during the method.

The maintenance pump 230 is located on an outlet of the upstream reservoir 210 different from that to which the drain pipe 221 is connected, and is connected to said drain pipe 211 at some distance from the upstream reservoir 210.

The reserve pump 120 is connected to the control module 30.

The maintenance pump 230 allows to increase the circulation flow rate of the new cooling liquid and to prevent the pressure drops induced by the various elements of the liquid cooling circuit 10A from being too great and preventing the injection of new cooling liquid.

Alternatively, in at least one embodiment, the maintenance pump 230 may not be present in the circuit.

Alternatively, in at least one embodiment, the drain pipe 211 may be connected directly to the outlet of the maintenance pump 230.

### Control Module 30

The control module 30 allows an operator to control the maintenance unit 20. It comprises a control interface 30A, allows an operating mode to be selected for the method and allows the maintenance pump 230 to be controlled.

Preferably, in at least one embodiment, the control module 30 is located in the maintenance unit 20.

Advantageously, by way of one or more embodiments, the control module 30 may be connected to the rack 10 to control the main pump 110 and the reserve pump 120 as shown in FIG. 3.

Alternatively, in at least one embodiment, the control module 30 may be located either inside the rack 10 or independently outside the rack 10 and the maintenance unit 20.

### Example of Implementation

Preferably, in at least one embodiment, the maintenance unit 20 is removable and movable.

Before the method is triggered, the maintenance unit 20 is therefore moved close to the rack 10 whose cooling liquid of the liquid cooling circuit 10A needs to be changed. The active elements of the computing blades contained in the rack 10 are switched on.

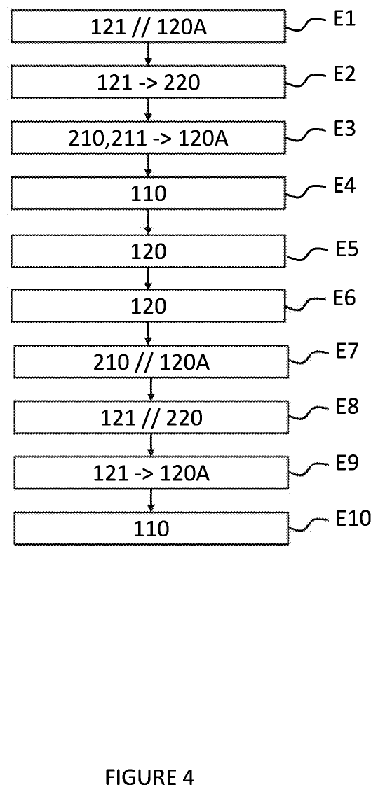

FIG. 4 illustrates the steps in the method according to one or more embodiments of the invention. In step E1, the inlet supply pipe 121 of the reserve pump 120 is disconnected.

In step E2, the drain pipe 211 of the upstream reservoir 210 of the maintenance unit 20 is connected to the inlet orifice 120A of the reserve pump 120.

In step E3, the inlet supply pipe 121 of the reserve pump 120 disconnected in step E1 is connected to the downstream reservoir 220 of the maintenance unit 20.

Following step E3, the assembly 1 formed by the rack 10 and the maintenance unit 20 is shown in FIG. 2, by way of one or more embodiments.

Once the maintenance unit 20 is connected to the rack 10, step E4 is to stop the main pump 110.

Step E5 activates the reserve pump 120. Once this step has been completed, the reserve pump 120 draws the new cooling liquid contained in the upstream reservoir 210 into the liquid cooling circuit 10A via the drain pipe 211 and the used cooling liquid flows into the downstream reservoir 220 via the inlet supply pipe 121.

Preferably, in at least one embodiment, steps E4 and E5 are implemented automatically when the operator activates a maintenance mode on the rack 10.

Even more preferably, in at least one embodiment, the maintenance pump 230 is also activated during or after step E5 to counterbalance the pressure drops in the flow of the new cooling liquid. The maintenance pump 230 is triggered by the operator from the control module 30 of the maintenance unit 20.

In a first operating mode, the control module 30 allows the operator to adjust the flow rate of the maintenance pump 230 via its control interface 30A. The flow rate of the main pump 110 and of the reserve pump 120 is controlled by the maintenance mode of the rack 10.

In a second operating mode, the control module 30 allows the operator to select a program which automatically controls the adjustment of the maintenance pump 230 via its control interface 30A. The flow rate of the main pump 110 and of the reserve pump 120 is controlled by the maintenance mode of the rack 10.

Alternatively, in at least one embodiment, the main pump 110, the reserve pump 120 and the maintenance pump 230 may be adjusted manually by the operator.

Step E5 ends when the new cooling liquid contained in the upstream reservoir 210 is below a predetermined low threshold, and all the cooling liquid in the liquid cooling circuit 10A has been changed.

Preferably, in at least one embodiment, the upstream reservoir 210 is equipped with a liquid level sensor 210A connected to or communicating with the control module 30 of the maintenance unit 20. This liquid level sensor 210A sends information that the new cooling liquid contained in the upstream reservoir 210 is below a predetermined low threshold and the control module 30 triggers the next step E6.

As an alternative or in addition, in at least one embodiment, the upstream reservoir 210 has a graduated transparent wall which allows the operator to visually check the cooling liquid level.

In a step E6, the reserve pump 120 is stopped once the new cooling liquid contained in the upstream reservoir 210 is below a predetermined low threshold.

In a step E7, the drain pipe 211 of the upstream reservoir 210 is disconnected from the inlet orifice 120A of the reserve pump 120.

In a step E8, the inlet supply pipe 121 of the reserve pump 120 is disconnected from the downstream reservoir 220.

Alternatively, in at least one embodiment, the order of steps E7 and E8 may be swapped.

In a step E9, the inlet supply pipe 121 is reconnected to the inlet orifice 120A of the reserve pump 120.

In step E10, the main pump 110 is reactivated and the new cooling liquid circulates in the liquid cooling circuit 10A.

Preferably, in at least one embodiment, steps E6 and E10 are implemented automatically by the operator activating a maintenance mode on the rack 10.

Alternatively, in at least one embodiment, step E10 may be performed between steps E6 and E7.

The active elements of the computing blades contained in the rack 10 did not need to be stopped when the cooling liquid was replaced, since the alternating operation of the main pump 110 and of the reserve pump 120 allowed a circulation of cooling liquid to be maintained in the computing blade heat exchanger 130.

At the end of the method, the cooling liquid in the liquid cooling circuit 10A has been changed and the rack 10 and the maintenance unit 20 are no longer fluidically connected. The maintenance unit 20 may then be moved to empty the used cooling liquid recovered during the method and to refill the upstream reservoir 210 with new cooling liquid in preparation for another replacement operation of the cooling liquid.

In a variant, by way of one or more embodiments, the method comprises in step E5 a temporary reactivation of the main pump 110 when the new cooling liquid is drawn into the liquid cooling circuit 10A in order to purge the used cooling liquid which is trapped in the main pump 110 and replace it with new cooling liquid.

1. A method for replacing a liquid in a liquid cooling circuit of a supercomputer rack by means of a maintenance unit, said supercomputer rack comprising the liquid cooling circuit, a main pump mounted in said liquid cooling circuit, and a reserve pump mounted in parallel with said main pump via an inlet supply pipe connected upstream from said main pump and an outlet supply pipe connected downstream from said main pump, said maintenance unit comprising an upstream reservoir for new cooling liquid and a downstream reservoir for recovering used cooling liquid, said method comprising:
disconnecting the inlet supply pipe from the reserve pump,
connecting the inlet supply pipe to the downstream reservoir,
connecting the upstream reservoir to an inlet of the reserve pump via a pipe comprising a drain pipe,
stopping the main pump,
activating the reserve pump so as to circulate the new cooling liquid from the upstream reservoir to the downstream reservoir via the reserve pump,
stopping the reserve pump once the new cooling liquid in the upstream reservoir is below a predetermined low threshold,
disconnecting the drain pipe to disconnect the upstream reservoir from the reserve pump,
disconnecting the inlet supply pipe from the downstream reservoir,
connecting the inlet supply pipe to the inlet of the reserve pump in order to return said reserve pump to its initial configuration,
reactivating the main pump.

2. The method according to claim 1, wherein the stopping the main pump, the activating the reserve pump, the stopping the reserve pump once the upstream reservoir is below the predetermined low threshold and the reactivating the main pump are carried out automatically.

3. The method according to claim 1, wherein, the maintenance unit comprising a maintenance pump at an outlet of the upstream reservoir, said maintenance pump being connected to the reserve pump via the drain pipe, the method further comprises activating said maintenance pump.

4. A supercomputer cooling liquid drain system, said supercomputer cooling liquid drain system comprising:
a supercomputer rack configured to receive computing blades and comprising a liquid cooling circuit, a main pump mounted in said liquid cooling circuit and a reserve pump mounted in parallel with said main pump,
a removable maintenance unit comprising an upstream reservoir for new cooling liquid and a downstream reservoir for recovering used cooling liquid, each configured to be connected to the supercomputer rack,
a control module configured to control the main pump and the reserve pump of the supercomputer rack.

5. The supercomputer cooling liquid drain system according to claim 4, wherein the control module is configured to, in an automatic maintenance mode, automatically carry out a sequence of
command a stop of the main pump,
then command an activation of the reserve pump,
then command a stop of the reserve pump once the new cooling liquid in the upstream reservoir is below a predetermined low threshold,
then command a reactivation of the main pump.

6. The supercomputer cooling liquid drain system according to claim 5, wherein the automatic maintenance mode is configured to be triggered by an operator pressing a button on the control module.

7. The supercomputer cooling liquid drain system according to claim 4, wherein the control module is further configured to detect that the new cooling liquid in the upstream reservoir is below a predetermined low threshold.

8. The supercomputer cooling liquid drain system according to claim 4, wherein the removable maintenance unit further comprises a maintenance pump at an outlet of the upstream reservoir, an outlet of said maintenance pump being configured to be connected to an inlet of the reserve pump of the supercomputer rack by a drain pipe, the control module being further configured to command activation of said maintenance pump.

9. The supercomputer cooling liquid drain system according to claim 8, wherein the control module is further configured to command activation of the reserve pump and activation of the maintenance pump simultaneously.

10. The supercomputer cooling liquid drain system according to claim 4, wherein the removable maintenance unit is further configured to detect during a drain operation that the upstream reservoir of the new cooling liquid is below a predetermined low threshold and to indicate to the control module or to an operator that the new cooling liquid in the upstream reservoir is below the predetermined low threshold.

11. The supercomputer cooling liquid drain system according to claim 4, wherein the removable maintenance unit further comprises at least one filter.

12. The supercomputer cooling liquid drain system according to claim 11, wherein the at least one filter is mounted at an inlet of the downstream reservoir.

13. The supercomputer cooling liquid drain system according to claim 4, wherein the control module is internal to the supercomputer rack.

14. The supercomputer cooling liquid drain system according to claim 4, wherein the control module is internal to the removable maintenance unit.

15. The supercomputer cooling liquid drain system according to claim 4, wherein the control module is external to the supercomputer rack and to the removable maintenance unit.
